(19) United States
(12) Patent Application Publication
(10) Pub. No.: US 2022/0140572 A1
(43) Pub. Date: May 5, 2022

(54) Dual Wavelength Visible Laser Source

(71) Applicant: Nuburu, Inc., Centennial, CO (US)

(72) Inventors: Jean-Philippe Feve, Monument, CO (US); Mark Zediker, Castle Rock, CO (US)

(73) Assignee: Nuburu, Inc., Centennial, CO (US)

(21) Appl. No.: 17/343,691

(22) Filed: Jun. 9, 2021

Related U.S. Application Data
(60) Provisional application No. 63/036,964, filed on Jun. 9, 2020.

(51) Int. Cl. H01S 5/40; H01S 5/02253

(52) U.S. Cl. CPC H01S 5/4087; H01S 5/02253

(57) ABSTRACT

The dual wavelength laser diode module is a module that consists of two or more wavelengths separated by 10 nm or more nm with the goal to produce an output beam of two different wavelength beams that are not-colinear. Providing to two separate lines in the focal point of a Fourier transform lens.

This application claims priority to and under 35 U.S.C. § 119(e)(1) the benefit of the filing date of U.S. provisional application Ser. No. 63/036,964, filed Jun. 9, 2020, the entire disclosure of which is incorporated herein by reference.

### BACKGROUND OF THE INVENTION

### Field of the Invention

The present inventions relate to dual wavelength laser systems, beams and uses thereof.

As used herein, unless expressly stated otherwise, “UV”, “ultra violet”, “UV spectrum”, and “UV portion of the spectrum” and similar terms, should be given their broadest meaning, and would include light in the wavelengths of from about 10 nm to about 400 nm, and from 10 nm to 400 nm.

As used herein, unless expressly stated otherwise, the terms “high power”, “multi-kilowatt” and “multi-kW” lasers and laser beams and similar such terms, mean and include laser beams, and systems that provide or propagate laser beams that have at least 1 kW of power (are not low power, e.g., not less than 1 kW), that are at least 2 kW, (e.g., not less than 2 kW), that are at least 3 kW, (e.g., not less than 3 kW), greater than 1 kW, greater than 2 kW, greater than 3 kW, from about 1 kW to about 3 kW, from about 1 kW t about 5 kW, from about 2 kW to about 10 kW and other powers within these ranges as well as greater powers.

As used herein, unless expressly stated otherwise, the terms “visible”, “visible spectrum”, and “visible portion of the spectrum” and similar terms, should be given their broadest meaning, and would include light in the wavelengths of from about 380 nm to about 750 nm, and 400 nm to 700 nm.

As used herein, unless expressly stated otherwise, the terms “blue laser beams”, “blue lasers” and “blue” should be given their broadest meaning, and in general refer to systems that provide laser beams, laser beams, laser sources, e.g., lasers and diodes lasers, that provide, e.g., propagate, a laser beam, or light having a wavelength from about 400 nm to about 500 nm. Typical blue lasers have wavelengths in the range of about 405-495 nm. Blue lasers include wavelengths of 445 nm, about 445 nm, 450 nm, of about 450 nm, of 460 nm, of about 470 nm. Blue lasers can have bandwidths of from about 10 pm (picometer) to about 10 nm, about 2 nm, about 5 nm, about 10 nm and about 20 nm, as well as greater and smaller values.

As used herein, unless expressly stated otherwise, the terms “green laser beams”, “green lasers” and “green” should be given their broadest meaning, and in general refer to systems that provide laser beams, laser beams, laser sources, e.g., lasers and diodes lasers, that provide, e.g., propagate, a laser beam, or light having a wavelength from about 500 nm to about 575 nm. Green lasers include wavelengths of 515 nm, of about 515 nm, of 525 nm, of about 525 nm, of 532 nm, about 532 nm, of 550 nm, and of about 550 nm. Green lasers can have bandwidths of from about 10 pm to 10 nm, about 2 nm, about 5 nm, about 10 nm and about 20 nm, as well as greater and smaller values.

Generally, the term “about” as used herein, unless specified otherwise, is meant to encompass a variance or range of ±10%, the experimental or instrument error associated with obtaining the stated value, and preferably the larger of these.

As used herein, unless specified otherwise, the recitation of ranges of values, a range, from about “x” to about “y”, and similar such terms and quantifications, includes each item, feature, value, amount or quantity falling within that range. As used herein, unless specified otherwise, each and all individual points within a range are incorporated into this specification, are a part of this specification, as if it were individually recited herein.

This Background of the Invention section is intended to introduce various aspects of the art, which may be associated with embodiments of the present inventions. Thus, the forgoing discussion in this section provides a framework for better understanding the present inventions, and is not to be viewed as an admission of prior art.

### SUMMARY

The present inventions advance the art and solves the long standing need for improving lasers, and laser systems, for imaging, projection, analysis and other medical, industrial and entertainment applications. The present inventions, among other things, advances the art and solves these problems and needs by providing the articles of manufacture, devices and processes taught, and disclosed herein.

A dual color laser beam system, the system having: a first laser module having a plurality of laser diode assemblies, each assembly providing an initial laser beam; a second laser module having a plurality of laser diode assemblies, each assembly providing an initial laser beam; wherein the initial laser beams from the first laser module are blue, thereby defining a plurality of initial blue laser beams; wherein the initial laser beams from the second laser module are green; thereby defining a plurality of initial green laser beams; a means to combine the plurality of initial blue laser beams into a single blue laser beam along a single blue laser beam path and to combine the plurality of initial green laser beams into a single green laser beam along a single green laser beam path; wherein the single green laser beam path and the single blue laser beam path are not parallel and thereby provide a blue laser beam spot and a green laser beam spot.

A method of welding, cutting, or additive manufacturing (such as 3-D printing), using a dual color laser beam system, the system having: a first laser module having a plurality of laser diode assemblies, each assembly providing an initial laser beam; a second laser module having a plurality of laser diode assemblies, each assembly providing an initial laser beam; wherein the initial laser beams from the first laser module are blue, thereby defining a plurality of initial blue laser beams; wherein the initial laser beams from the second laser module are green; thereby defining a plurality of initial green laser beams; a means to combine the plurality of initial blue laser beams into a single blue laser beam along a single blue laser beam path and to combine the plurality of initial green laser beams into a single green laser beam along a single green laser beam path; wherein the single green laser beam path and the single blue laser beam path are not parallel and thereby provide a blue laser beam spot and a green laser beam spot; directing the dual laser beam to a target location containing a target material, wherein the target material is a metal, a foil sheet, a metal powder, or other material.

A multi-color laser system that creates N beams with an angular offset such that they create N separate spots or lines at the focal plane of an objective lens where N>2.

A method of welding, cutting, or additive manufacturing (such as 3-D printing), using a multi-color laser system that creates N beams with an angular offset such that they create N separate spots or lines at the focal plane of an objective lens where N>2; directing the dual laser beam to a target location containing a target material, wherein the target material is a metal, a foil sheet, a metal powder, or other material.

A multi-color laser system that creates N beams with an angular offset such that they create N separate spots or lines at the focal plane of an objective lens where N>1.

A method of welding, cutting, or additive manufacturing (such as 3-D printing), using a multi-color laser system that creates N beams with an angular offset such that they create N separate spots or lines at the focal plane of an objective lens where N>1; directing the dual laser beam to a target location containing a target material, wherein the target material is a metal, a foil sheet, a metal powder, or other material.

These systems and methods having one or more of the following features: a multi-color laser system where one spot has a wavelength of 400 nm-500 nm; a multi-color laser system where one spot has a wavelength of 501 nm-600 nm; a multi-color laser system where one spot has a wavelength of 601 nm-700 nm; wherin the objective lens used with the laser system is an achromat; wherein the objective lens used with the laser system is a cook triplet to compensate for any chromatic aberrations and spherical aberrations and place the two different wavelength beams at approximately the focal point of the objective lens; wherein the objective lens used with the laser system is a doublet to compensate for any chromatic aberrations and spherical aberrations and place the two different wavelength beams at approximately the focal point of the objective lens; wherein the objective lens used with the laser system is an asphere to compensate for any chromatic aberrations and spherical aberrations and place the two different wavelength beams at approximately the focal point of the objective lens; wherein the beam homogenizer used with the laser system is a light pipe; wherein the beam homogenizer used with the laser system is a diffractive optic element; wherein the beam homogenizer used with the laser system is a micro lens array; wherein the beam homogenizer used with the laser system is a micro lens array with a diffractive optic element; wherein a lens-system used with the laser to create equal size line widths is a cylindrical lens pair of appropriate magnification operating on both beams simultaneously which have different wavelengths or two cylindrical lens pairs of appropriate magnifications operating on each wavelength beam independently; wherein a lens-system is used with the laser to create equal size line widths is a cylindrical lens pair of appropriate de-magnification operating on both beams simultaneously which have different wavelengths, or two cylindrical lens pairs of appropriate de-magnifications operating on each wavelength beam independently; wherein the lens system is comprised of acylinder lenses to correct for any spherical aberrations in the system; wherein the lens system is comprised of achromatic cylindrical lenses to compensate for any chromatic aberrations which would impact the magnification of the beamlets; wherein the lens system is comprised of cylindrical cook triplets to compensate for any chromatic aberrations and spherical aberrations which would impact the magnification of the beamlets; wherein the lens system is comprised of cylindrical doublets to compensate for any chromatic aberrations and spherical aberrations which would impact the magnification of the beamlets; wherein the lens system is comprised of acylinder lenses to compensate for any spherical aberrations which would impact the magnification or de-magnification of the beamlets; wherein the lens system is comprised of achromatic cylindrical lenses to compensate for any chromatic aberrations which would impact the magnification of the beamlets; wherein the lens system is comprised of cylindrical cook triplets to compensate for any chromatic aberrations and spherical aberrations which would impact the de-magnification of the beamlets; wherein the laser system is air cooled; wherein the laser system is liquid cooled; wherein the laser system operates in continuous mode; wherein the laser system is modulated at a pre-determined rate; wherein the laser system uses spatially combined laser diodes to achieve the required power and beam parameters; wherein the laser system uses wavelength combined laser diodes to achieve the required power and beam parameters; wherein the laser system uses polarization combined laser diodes to achieve the required power and beam parameters; wherein the laser system which uses spatially combined laser diodes in combination with wavelength combined laser diodes to achieve the required power and beam parameters; wherein the laser system which uses spatially combined laser diodes in combination with polarization combined laser diodes to achieve the required power and beam parameters; wherein the laser system which uses spatially combined laser diodes in combination with polarization combined laser diodes and wavelength combined laser diodes to achieve the required power and beam parameters; wherein the laser system is used in medical applications; wherein the laser system is used in medical diagnostic applications; wherein the laser system is used in industrial applications; wherein the laser system is used in projection applications; wherein N>2; N>3; N>4; wherein the laser system consist of diode lasers; wherein the laser system has a diode laser; wherein the single blue laser beam and the single green laser beam have wavelengths that are at least 10 nm different; and, wherein the single blue laser beam and the single green laser beam have wavelengths that are at least 30 nm different.

### BRIEF DESCRIPTION OF THE DRAWINGS

FIG. 1 is a perspective schematic view of an embodiment of a laser system in accordance with the present inventions.

FIG. 2 is a schematic plan view of an embodiment of a special combination of four laser systems in accordance with the present inventions.

FIG. 3 is a plan view schematic of an embodiment of the combination of laser beams having different wavelengths in accordance with the present inventions.

FIG. 4 is a graphic illustration of an embodiment of a near-field composite two-color laser beam in accordance with the present inventions.

FIG. 5 is a graphic illustration of an embodiment of a far-field composite two-color laser beam in accordance with the present inventions

### DESCRIPTION OF THE PREFERRED EMBODIMENTS

In general, the present inventions relate to multiple wavelength laser systems and uses thereof. In particular, in an embodiment, the present inventions relate to dual wavelength laser systems, using diode lasers.

The present inventions can have one, two, three four, five, ten or more diode lasers. All of the laser sources in the systems can be diode laser, while other laser sources may also be used with diode laser sources in the systems. The laser system can be a combination of one, two, three, four, five or more laser sub-systems, with each laser sub-system having one, two, three, four, five, ten or more laser sources, such as laser diodes.

The present inventions can have two, three, four, five, ten or more laser beams, preferably with each having a separate, e.g., different, wavelength. Each of the wavelengths in these systems is separated by about 1 nm, at least 1 nm, about 2 nm, at least 2 nm, about 5 nm, at least 5 nm, at least 10 nm, about 10 nm, 15 nm, about 15 nm, 20 nm, about 20 nm, at least 10 nm, at least 20 nm, at least 30 nm, from about 10 nm to about 50 nm, and greater and smaller amounts of separation.

In embodiments the separate laser beams in these multiwavelength systems are also not colinear. The axis of their beam propagations, i.e., the line formed by their beam paths are not parallel, and are not colinear.

Generally, in these types of dual wavelength systems, multiple laser beams of the same color group (having the same or slightly different (e.g., 1 nm to about 5 nm) wavelengths, but still within the same color), e.g., blue or green, can be combined into single blue laser beam (having blue laser beam path) and a single green laser beam (having a green laser beam path). The combined blue and green laser beams are not parallel, and are focused into two spot, i.e., a green spot and a blue spot. The multiple blue and green laser beams can be combined into two non-parallel laser beams with a single optical element, such as a dichroic filter. Thus, 4, 6, 8, 10 or more parallel laser beams of two different color groups can be shaped by a single optical element into two non-parallel laser beams, which each beam having one of the different color groups, and forming dual laser spots of the different colors at the focal point of a lens.

Although the specification focus on the color different color groups as blue and green, it should be understood that the benefits of the present inventions are obtained when the different color groups separated by at least about 10 nm, at least about 20 nm, and about 40 nm to 80 nm, as well as, other differences.

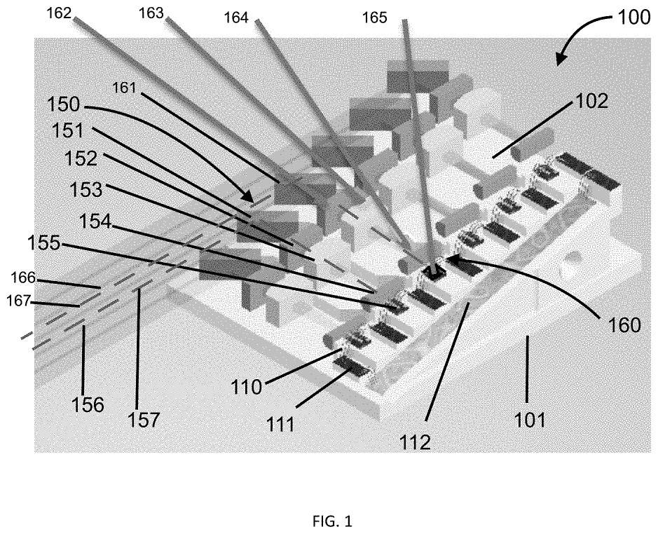

Turning to FIG. 1 there is shown a perspective schematic view of an embodiment of the present multiwavelength systems. The laser module 100, has six laser diode assemblies, and thus could be considered a Lensed Hexel. (It being understood that the module 100 could have four, five, seven or more, ten or more laser diode assemblies. Two of the laser diode assemblies, 150, 160 have been labeled. Each of the laser modules are mounted on a base 101, and are associated with a heat sink 102, which is also associated with, and can be, the base 101. The laser diode assemblies, e.g., 150, 160, have a laser diode, e.g., 155, 165, a fast axis collimating lens (FAC), e.g., 164, 154, a short axis collimating lens (SAC), e.g., 163, 153, a variable brag grating (VBG), e.g., 162, 163, and a reflective/combining element, e.g., 161, 151. In the arrangement of FIG. 1 the laser beams, e.g., 166, 156, and their beam paths 167, 157 are parallel but not collinear. The six laser beams are spatially combined, without overlapping, to provide a single combined laser beam at a focal point of a lens.

The laser beams can be the same wavelength or different wavelengths.

In embodiments the laser beams are combined by the reflective/combining elements to be colinear. In this embodiment, preferably the VBG filter out all but a single wave length that is different from the other VBGs by only a few nm, (e.g., 1, 2, 5 nm), thus the combined colinear beam can have six beam having wavelengths λ1, λ1+1 nm, λ1+2 nm, λ1+3 nm, λ1+4 nm, and λ1+5 nm.

In embodiments, a first group of laser diode assemblies (e.g., three laser diode assemblies of FIG. 1) all have wavelengths in a first color grouping, e.g., blue; and a second group of laser diode assemblies (e.g., three laser diode assemblies) all have wavelengths in a second color grouping, e.g., green. The laser beams in the blue group are all combined (spatially as parallel beams filling the space between them; or preferably as colinear beams along a single laser beam path for the first color grouping). The laser beams in the green group are all combined (spatially as parallel beams filling the space between them; or preferably as colinear beams along a single laser beam path for the second color grouping). In the embodiment the first and second combined laser beam paths are not parallel, instead that are preferably diverging at a sight angle. Thus, having a laser system with dual wavelength non-parallel laser beams.

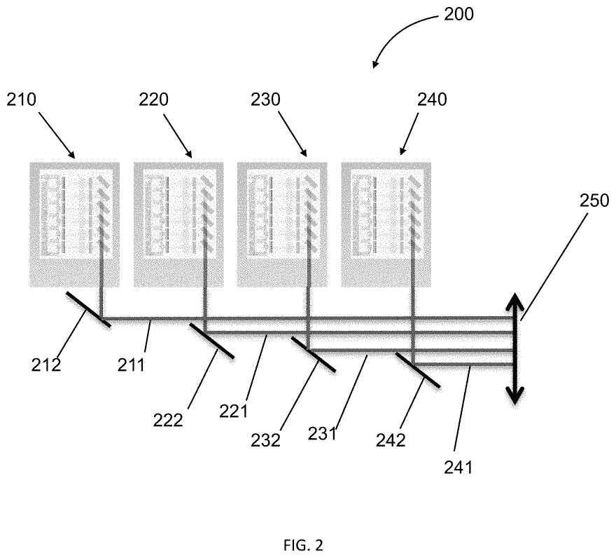

Turning to FIG. 2, there is shown a plan schematic view of an embodiment of a laser system 200. The laser system 200 has four laser modules 210, 220, 230, 240. These laser modules can be the same or they can be different. In the embodiment as shown the laser modules are Lensed Hexels. They can be Lensed Hexels of any of the types of configurations discussed above with the schematic of FIG. 1. Each laser module has a turning/combining element, 212, 222, 232, 242. That turn and combine the laser beams 211, 221, 231, 241 from the laser modules traveling along laser beam paths. The system has a lens 250, preferably a focusing lens, and more preferably an achromat focusing lens.

In an embodiment of the system of FIG. 2, the laser beams and their beam paths, after the turning/combining elements, are parallels, not colinear, and spatially combined into a single beam prior to entering the lens 250. These beam paths may also be spatially combined into a single spot by lens 250 at its focal point.

In an embodiment of the system of FIG. 2, the laser beams and their beam paths, after the turning/combining elements, are colinear (by definition colinear beams are parallel), and thus in a single beam along a single beam path prior to entering the lens 250.

In an embodiment of the system of FIG. 2, laser modules 210 and 220 produce a blue laser beam, and laser modules 230 and 240 produce a green laser beam. Blue laser beams, 211, 221, after the turning/combining elements, are colinear and thus in a single blue laser beam along a single blue laser beam path prior to entering the lens 250. Green laser beams, 231, 241, after the turning/combining elements, are colinear and thus in a single green laser beam along a single green laser beam path prior to entering the lens 250. Single green laser beam path, and single blue laser beam path, and thus their respective laser beams, are not colinear, not parallel, and are preferably diverging. Thus, having a laser system with dual wavelength non-parallel laser beams.

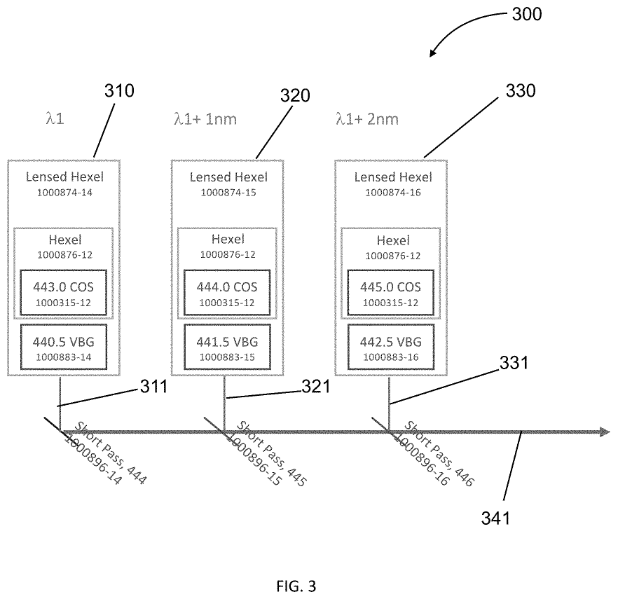

Turning to FIG. 3 there is shown a plan schematic view of a laser system 300. The laser system has three laser modules, 310, 320, 330. These laser modules can each have six laser diode assemblies. Laser module 310 provides laser beam 311 having a first wavelength. Laser module 320 provides a laser beam 321 having a second wavelength, which is different from the first wavelength, by from about 1 nm to about 10 nm. Laser module 330 provides a laser beam 331 having a third wavelength, which is different from the first wavelength and the second wavelength, by from about 1 nm to about 10 nm. The laser beams 311, 321, 331 are combined by combining elements to be colinear and thus provide a colinear laser beam 341. The colinear laser beams can be combined to a single spot in the focal plane of a lens.

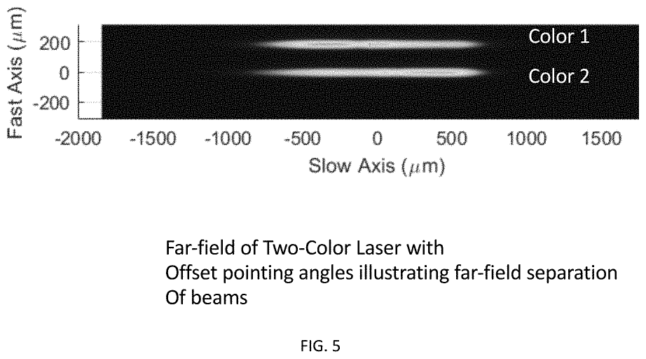

The system 300 provides a set of colinear laser beams 341 that are blue. The system 300 can be combined into a dual wavelength laser system with a similar laser system to system 300, but providing a set of green (colinear) laser beams. The blue laser beams and the green laser beams are on beam paths that are not parallel and are focused, by an optical element, e.g., focusing lens, into two spots, such as for example the spots as shown in FIG. 5.

The following examples are provided to illustrate various embodiments of the present laser systems and components of the present inventions. These examples are for illustrative purposes, may be prophetic, and should not be viewed as limiting, and do not otherwise limit the scope of the present inventions.

### EXAMPLE 1

The dual wavelength laser diode module is a module that consists of two or more wavelengths separated by 10 nm or more nm with the goal to produce an output beam of two different wavelength beams that are not-colinear. By producing two beams that have a slightly different pointing angle, it is possible to create two separate lines in the focal point of a Fourier transform lens. A line is created naturally because the laser diodes are near diffraction limited in the one axis and highly multi-mode in the other. The highly multi-mode axis has a much higher angle of divergence and when focused by a single lens element the result is a line focus. These two lines are homogenized to provide less than a 20% variation in output power over the length of the lines. This type of dual line module is ideal for use in a wide range of medical and industrial applications as an illuminator when differentially targeting a material to provide a signal that can be processed to identify the material being targeted.

### EXAMPLE 2

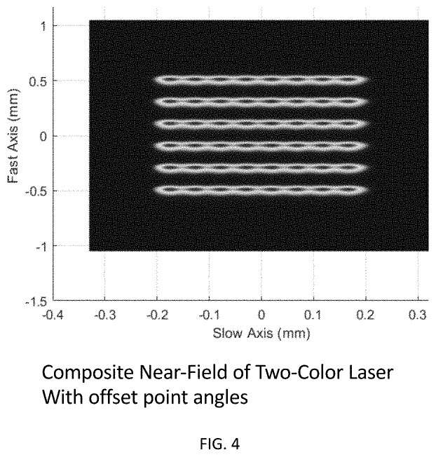

An embodiment has two wavelengths of laser diodes, one at 445 nm and the other at 525 nm. The absolute wavelengths may vary. The power for the illumination system may be relatively low, a few watts, or for much higher processing speeds be about one kWatt (kW), or greater . Commercially available laser diodes are presently available at 445 nm are capable of making the line focus at the power levels of a few Watts to multi-kWatts. In embodiments where the target material has a broad absorption bandwidth, the laser diode array may be up to 10 nm in bandwidth to accommodate a high number of laser diodes. Laser diodes at 445 nm are commercially presently available at power levels up to about 5 Watts, this power will increase substantially, allowing the bandwidth of the system for a given power level to be decreased. Commercially available green laser diodes at 525 nm are presently available as single mode devices up to about 100 mW of power, and multi-mode devices at power levels up to about 1.5 Watts continuous wave. Either type of green laser diode may be used, it being understood that the lower power diodes will require more diodes, and more complexity to achieve the power levels required for typical systems in use today. The laser diodes may be bonded to a heat sink as shown in FIG. 1, they may be in a can, such as a TO-9 or TO-5.6 or TO-3.8, or they may be a laser diode bar. All three require the same approach to collimation, a cylindrical lens pair collimates the fast axis and the slow axis. A fast axis collimation lens is attached to the heat sink to collimate the fast diverging axis of the laser diode. A second, slow axis collimation lens is attached to the heat sink to collimate the slow diverging axis of the laser. Alternatively, the collimation lenses can be attached to a secondary mount. For low power applications, the Volume Bragg Grating called out in FIG. 1 may not be necessary. But to preserve brightness at higher power levels the Volume Bragg Grating is used to enable the spectral beam combining of beams at high power. All the diodes that are bonded to the heat sink for one color set such as “blue” are aligned to be parallel and when spectrally combined to be colinear. Similarly, all of the diodes that are bonded for the color set of “green” are aligned to be parallel and when spectrally combined to be co-linear, as shown in FIG. 4. However, the two different color sets are now aligned with a slight difference in point angle which will result in the spatial separation of the blue color from the green color in the focal plane of the lens. The lens in this case is an achromatic lens which is compensated for the difference in the colors and enables both colors to come into focus at the same time. The beams prior to being launched may pass through a telescope to condition them to the right divergence parameters to create the desired line. Alternatively, two telescopes can be used prior to condition the “blue” and “green” beams independently, prior to combining them. After the telescope(s), the beams are then passed through a homogenizer to create a uniform, or near uniform intensity distribution along the line. The resulting line pattern is shown in FIG. 5 where the blue and the green beams have a pointing angle difference of 4.2 mrad.

It is noted that there is no requirement to provide or address the theory underlying the novel and groundbreaking processes, materials, performance or other beneficial features and properties that are the subject of, or associated with, embodiments of the present inventions. Nevertheless, various theories are provided in this specification to further advance the art in this area. The theories put forth in this specification, and unless expressly stated otherwise, in no way limit, restrict or narrow the scope of protection to be afforded the claimed inventions. These theories may not be required or practiced utilizing the present inventions. It is further understood that the present inventions may lead to new, and heretofore unknown theories to explain the function-features of embodiments of the methods, articles, materials, devices and system of the present inventions; and such later developed theories shall not limit the scope of protection afforded the present inventions.

The various embodiments of systems, equipment, techniques, methods, activities and operations set forth in this specification may be used for various other activities and in other fields in addition to those set forth herein. Additionally, these embodiments, for example, may be used with: other equipment or activities that may be developed in the future; and with existing equipment or activities which may be modified, in-part, based on the teachings of this specification. Further, the various embodiments set forth in this specification may be used with each other in different and various combinations. Thus, for example, the configurations provided in the various embodiments of this specification may be used with each other; and the scope of protection afforded the present inventions should not be limited to a particular embodiment, configuration or arrangement that is set forth in a particular embodiment, example, or in an embodiment in a particular Figure.

The invention may be embodied in other forms than those specifically disclosed herein without departing from its spirit or essential characteristics. The described embodiments are to be considered in all respects only as illustrative and not restrictive.

1. A multi-color laser system that creates N beams with an angular offset such that they create N separate spots or lines at the focal plane of an objective lens where N≥2.

2. A multi-color laser system of claim 1 where one spot has a wavelength of 400 nm-500 nm.

3. A multi-color laser system of claim 1 where one spot has a wavelength of 501 nm-600 nm.

4. A multi-color laser system of claim 1 where one spot has a wavelength of 601 nm-700 nm.

5. The objective lens used with the laser system in claim 1 is an achromat.

6. The objective lens used with the laser system of claim 1 is a cook triplet to compensate for any chromatic aberrations and spherical aberrations and place the two different wavelength beams at approximately the focal point of the objective lens.

7. The objective lens used with the laser system of claim 1 is a doublet to compensate for any chromatic aberrations and spherical aberrations and place the two different wavelength beams at approximately the focal point of the objective lens.

8. The objective lens used with the laser system in claim 1 is an asphere to compensate for any chromatic aberrations and spherical aberrations and place the two different wavelength beams at approximately the focal point of the objective lens.

9. The beam homogenizer used with the laser system in claim 1 is a light pipe.

10. The beam homogenizer used with the laser system in claim 1 is a diffractive optic element.

11. The beam homogenizer used with the laser system in claim 1 is a micro lens array.

12. The beam homogenizer used with the laser in claim 1 is a micro lens array with a diffractive optic element.

13. A lens-system used with the laser in claim 1 to create equal size line widths is a cylindrical lens pair of appropriate magnification operating on both beams simultaneously which have different wavelengths or two cylindrical lens pairs of appropriate magnifications operating on each wavelength beam independently.

14. A lens-systems used with the laser in claim 1 to create equal size line widths is a cylindrical lens pair of appropriate de-magnification operating on both beams simultaneously which have different wavelengths, or two cylindrical lens pairs of appropriate de-magnifications operating on each wavelength beam independently.

15. The lens systems of claim 13 is comprised of acylinder lenses to correct for any spherical aberrations in the system.

16. The lens systems of claim 13 is comprised of achromatic cylindrical lenses to compensate for any chromatic aberrations which would impact the magnification of the beamlets.

17. The lens system of claim 13 is comprised of cylindrical cook triplets to compensate for any chromatic aberrations and spherical aberrations which would impact the magnification of the beamlets.

18. The lens system of claim 13 is comprised of cylindrical doublets to compensate for any chromatic aberrations and spherical aberrations which would impact the magnification of the beamlets.

19. The lens systems of claim 14 is comprised of acylinder lenses to compensate for any spherical aberrations which would impact the magnification or de-magnification of the beamlets.

20. The lens systems of claim 14 is comprised of achromatic cylindrical lenses to compensate for any chromatic aberrations which would impact the magnification of the beamlets.

21. The lens system of claim 14 is comprised of cylindrical cook triplets to compensate for any chromatic aberrations and spherical aberrations which would impact the de-magnification of the beamlets.

22. The laser system of claim 1 is air cooled.

23. The laser system of claim 1 is liquid cooled.

24. The laser system of claim 1 operates in continuous mode.

25. The laser system of claim 1 is modulated at a pre-determined rate.

26. The laser system of claim 1 uses spatially combined laser diodes to achieve the required power and beam parameters.

27. The laser system of claim 1 uses wavelength combined laser diodes to achieve the required power and beam parameters.

28. The laser system of claim 1 uses polarization combined laser diodes to achieve the required power and beam parameters.

29. The laser system of claim 1 which uses spatially combined laser diodes in combination with wavelength combined laser diodes to achieve the required power and beam parameters.

30. The laser system of claim 1 which uses spatially combined laser diodes in combination with polarization combined laser diodes to achieve the required power and beam parameters.

31. The laser system of claim 1 which uses spatially combined laser diodes in combination with polarization combined laser diodes and wavelength combined laser diodes to achieve the required power and beam parameters.

32. The laser system of claim 1 is used in medical applications.

33. The laser system of claim 1 is used in medical diagnostic applications.

34. The laser system of claim 1 is used in industrial applications.

35. The laser system of claim 1 is used in projection applications.

36. The laser systems of claims 1 to 35 wherein N≥2.

37. The laser systems of claims 1 to 35 wherein N≥3.

38. The laser systems of claims 1 to 37 consisting of diode lasers.

39. The laser systems of claims 1 to 37 comprising a diode laser.

40. A dual color laser beam system, the system comprising:
a. a first laser module comprising a plurality of laser diode assemblies, each assembly providing an initial laser beam;
b. a second laser module comprising a plurality of laser diode assemblies, each assembly providing an initial laser beam;
c. wherein the initial laser beams from the first laser module are blue, thereby defining a plurality of initial blue laser beams;
d. wherein the initial laser beams from the second laser module are green; thereby defining a plurality of initial green laser beams;
e. a means to combine the plurality of initial blue laser beams into a single blue laser beam along a single blue laser beam path and to combine the plurality of initial green laser beams into a single green laser beam along a single green laser beam path;
f. wherein the single green laser beam path and the single blue laser beam path are not parallel and thereby provide a blue laser beam spot and a green laser beam spot.

41. The system of claim 40, wherein the single blue laser beam and the single green laser beam have wavelengths that are at least 10 nm different.

42. The system of claim 40, wherein the single blue laser beam and the single green laser beam have wavelengths that are at least 30 nm different.
